(19) United States
(12) Patent Application Publication
(10) Pub. No.: US 2023/0057479 A1
(43) Pub. Date: Feb. 23, 2023

(54) DIGITAL TWIN WITH MACHINE LEARNING WAVEFORM GENERATION INCLUDING PARAMETER CONTROL FOR DEVICE UNDER TEST EMULATION

(71) Applicant: Tektronix, Inc., Beaverton, OR (US)

(72) Inventors: John J. Pickerd, Hillsboro, OR (US); Justin E. Patterson, Portland, OR (US); Heike Tritschler, Louisville, CO (US)

(21) Appl. No.: 17/893,073

(22) Filed: Aug. 22, 2022

Related U.S. Application Data
(60) Provisional application No. 63/235,653, filed on Aug. 20, 2021.

(51) Int. Cl. G01R 31/317; G01R 31/28; G06N 20/00

(52) U.S. Cl. CPC G01R 31/31713; G01R 31/2834; G06N 20/00

(57) ABSTRACT

A device for generating waveforms includes a machine learning system configured to associate waveforms from a device under test to parameters, a user interface configured to allow a user to provide one or more user inputs, and one or more processors configured to execute code that causes the one or more processors to receive one or more inputs through the user interface that include one or more parameters, apply the machine learning system to the received one or more parameters, produce, by the machine learning system, a waveform based on the one or more parameters, and output the produced waveform. Methods of generating waveforms are also presented.

### CROSS-REFERENCE TO RELATED APPLICATIONS

This disclosure claims benefit of U.S. Provisional Application No. 63/235,653, titled “DIGITAL TWIN WITH MACHINE LEARNING WAVEFORM GENERATION INCLUDING PARAMETER CONTROL FOR DEVICE UNDER TEST EMULATION,” filed on Aug. 20, 2021, the disclosure of which is incorporated herein by reference in its entirety.

### TECHNICAL FIELD

This disclosure relates to test and measurement systems, and more particularly to a system for emulating device under test parameter interactions with a waveform generator.

### BACKGROUND

Manufacturers of electrical and optical components test the components before sending them to their customers. Testing of optical and electrical components on manufacturing lines typically involves setting operating parameters for a component, testing it to gather output data, and then evaluating the output data to determine whether the component passes or fails the testing regimen. This testing process may occur hundreds of times for each component. This testing process raises the cost of manufacturing for each component, multiplied by the number of components, which can number in the thousands or hundreds of thousands for some manufacturers.

Further, the testing itself is time consuming because device parameters of the device being tested should be tested in all modes of operation. Running automated test scripts may reduce some of the burden of testing devices, but oftentimes machines being tested either do not have built-in automated testing modes, or such testing modes are not available early in development, when they are most needed. And many devices lack automated test modes entirely, so there is no automated testing available for those devices.

Embodiments according to the disclosure address these and other deficiencies in the field.

### BRIEF DESCRIPTION OF THE DRAWINGS

FIG. 1 is a system block diagram including a machine learning training network for a Device Under Test (DUT) using simulated waveforms, according to embodiments of the disclosure.

FIG. 2 is a system block diagram including a machine learning training network for a Device Under Test (DUT) using actual waveforms, according to embodiments of the disclosure.

FIG. 3 is a system block diagram of a trained machine learning network used to generate simulated electrical waveforms based on user inputs, according to embodiments of the disclosure.

FIG. 4 is a system block diagram of a trained machine learning network used to generate simulated optical waveforms based on user inputs, according to embodiments of the disclosure.

FIG. 5 is a system block diagram of an arbitrary waveform generator including a machine learning network for generating simulated electrical waveforms based on user inputs, according to embodiments of the disclosure.

FIG. 6 is another system block diagram of an arbitrary waveform generator including a machine learning network for generating simulated electrical waveforms based on user inputs, according to embodiments of the disclosure.

FIG. 7 is a system block diagram of an arbitrary waveform generator including a machine learning network for generating simulated optical waveforms based on user inputs, according to embodiments of the disclosure.

### DESCRIPTION

It is expensive and time consuming to design and build optical and electrical transceivers. One time-consuming aspect of the development is testing the characteristics of the device to ensure interoperability with multiple different receivers. If the design fails testing, a subsequent design is produced and tested. Each design iteration causes delays in the device development. Embodiments of the disclosed technology include creating a model of a transmitter device as a digital twin of the device itself. This digital twin learns waveform characteristics, based on parameters of a device under test (DUT), and generates waveforms that match those of the DUT. The digital twin waveform generator is then used, rather than the DUT itself, to test the interoperability of the DUT with multiple existing receiver types. The digital twin may include automated test scripting, and, in any event, may be easier to operate to generate the desired waveforms compared to the DUT itself. Another advantage to using a digital twin is that, as described below, the digital twin may be developed and operable before the DUT is physically available, while the DUT is still being designed. Thus, using a digital twin allows a developer to use the desired output of a DUT for testing before the DUT itself is even capable of producing the desired output.

In some embodiments, the DUT may be an optical transmitter. Other embodiments, however, are directed to devices that generate electrical signals. The digital twin device includes a machine learning network that operates in training mode or in operation (runtime) mode. As described below, the digital twin device is trained using either actual waveforms or simulated waveforms. In either case, in training mode, waveforms are associated as metadata to parameters that describe conditions that generated the particular waveforms. Then, in operation mode, the digital twin uses its trained machine learning network to select or produce a particular waveform based on parameters selected or provided by a user. The digital twin may control an Arbitrary Waveform Generator (AWG) to actually produce analog waveforms that may be applied by the user to test receiver characteristics. In other embodiments, the digital twin may be part of an AWG itself. These embodiments are described in detail below.

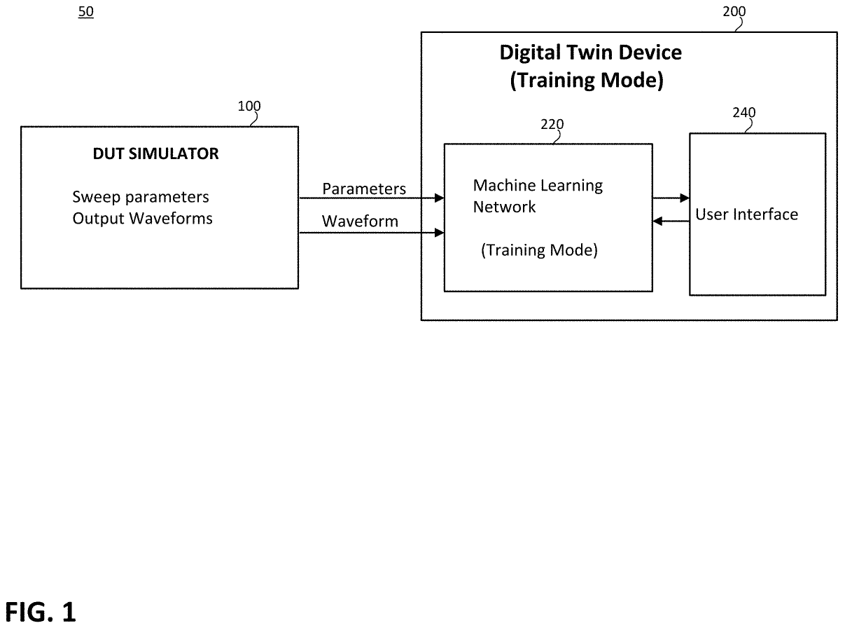

FIG. 1 is a system block diagram of a training system 50 including a machine learning training network for a Device Under Test (DUT) using simulated waveforms, according to embodiments of the disclosure. As described above, it is expensive to design, build, and test optical and electrical transceivers. And, typically, the desired waveforms that will be eventually generated by such a transceiver are available before the transceiver is fully developed. The training system 50 of FIG. 1 includes two main components—a DUT simulator 100 and a digital twin device 200. The digital twin device 200 may be embodied in software as an application running on one or more general purpose or special purpose processors, for example. The DUT simulator 100 stores a collection of desired output waveforms that will eventually be produced by a transmitter of a transceiver device. In general, the developer of the transceiver creates models of desired waveforms during development of the transceiver, and stores a copy of them in the DUT simulator 100, along with parameters used to create each waveform. This waveform development can be accomplished prior to ever building the transceiver.

After the DUT simulator 100 has acquired and stored the desired waveforms, the simulator passes each waveform and its associated parameters to the digital twin device 200. Generally, the user of the DUT simulator 100 operates the simulator to individually sweep through various ranges of values and combinations of parameters that produce the particular waveforms. These combinations of parameters and their related waveforms are stored in the DUT simulator 100. The parameters may include anything useful to classify the waveform in some manner. The input parameter data may include many different types of information. It may include transmitter tuning parameters, which are the various parameters in the transmitter register used to send the waveform. There may be dozens, or even hundreds of parameters. Other examples of parameter data include, without limitation: temperature, humidity, any type of measurement made on the waveform, the bandwidth of the response of the waveform data, an estimate of the transfer function of the media through which the waveform will be transmitted, FFE equalization taps, noise on the waveform, noise of the test and measurement device used to create or acquire the waveform, average optical power, jitter, etc. Thus, there are thousands of parameter combinations possible. Each possible parameter combination is associated with a waveform. Then the parameter combinations are associated with and stored with a waveform in the DUT simulator 100 for each combination.

After the various parameters and waveforms have been associated with one another the parameter data and waveform data are sent to the digital twin device 200 for training. During training, a machine learning network 220 operates in a training mode. The machine learning network 220 is controlled by a user interface 240, which may be a graphical user interface or a programmatic interface. In the training mode, the machine learning network 220 is provided with the parameters that produced a waveform as input for training. The waveforms produced by the parameters are provided as metadata, which the machine learning network uses to train its network. Specifically, the machine learning network 220 iterates on the parameters and their waveform metadata to correlate the waveforms to the parameters that created them. Further, the machine learning network 220, as part of its training, creates predictive models that accurately predict certain waveforms given a set of input parameters. Later, these predictions are used in the run-time modes of the digital twin device, as described below. In some embodiments, a user operates the user interface 240 to sweep from a minimum to a maximum of each of the controllable parameters used to produce a particular waveform for ingestion by the machine learning network 220. In this way the digital twin 200, through the machine learning network 220, teaches the digital twin to match particular waveforms with particular parameter settings. In some embodiments, the machine learning network 220 may use ResNet or RegNet networks, which operates on image data for learning. In these embodiments, the machine learning network 220 may use images of waveforms for training, rather than waveforms themselves.

The DUT simulator 100 may store parameters and waveform metadata for a single device, or the DUT simulator may store parameters and waveform metadata for multiple different devices. In general, parameters and waveform metadata from only a single one of the devices stored in the DUT simulator will be used for training the machine learning network 220 at any single time.

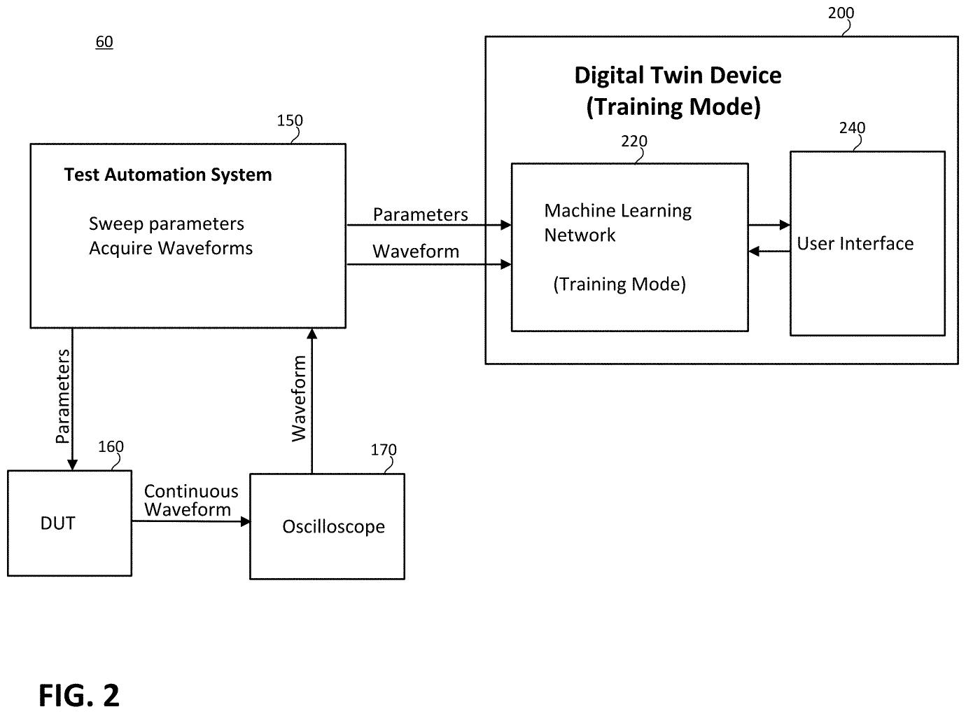

FIG. 2 is a system block diagram of a training system 60 including a machine learning training network for a DUT. Differently than the training system 50 of FIG. 1, the training system 60 of FIG. 2 uses actual, rather than simulated, waveforms for training the machine learning network 220. In the training system 60, an actual DUT already exists, so waveforms may be generated by the DUT without the need to simulate the waveforms, as in the system 50 of FIG. 1.

The training system 60 includes a test automation system 150, which controls a DUT 160. The DUT 160 receives parameters from the test automation system 150 and uses those parameters to generate a continuous waveform, which is sent to an oscilloscope 170. The oscilloscope receives the continuous waveform from the DUT 160 and generates a waveform output that matches or is related to the continuous waveform from the DUT 160. Then, similar to the training system 50 described with reference to FIG. 1, the test automation system 150 sends the parameters to the machine learning network 220 as well as the corresponding waveforms as metadata, for training. The machine learning network 220 in the digital twin device 200 operates in the same manner as described above, ingesting the parameters and waveform metadata and generating interconnected predictions between the waveforms and parameters to train the machine learning network 220.

After the machine learning network 220 in the digital twin device 200 is trained, a user may use the digital twin device 200 to generate selected waveforms for interoperability testing or for other uses.

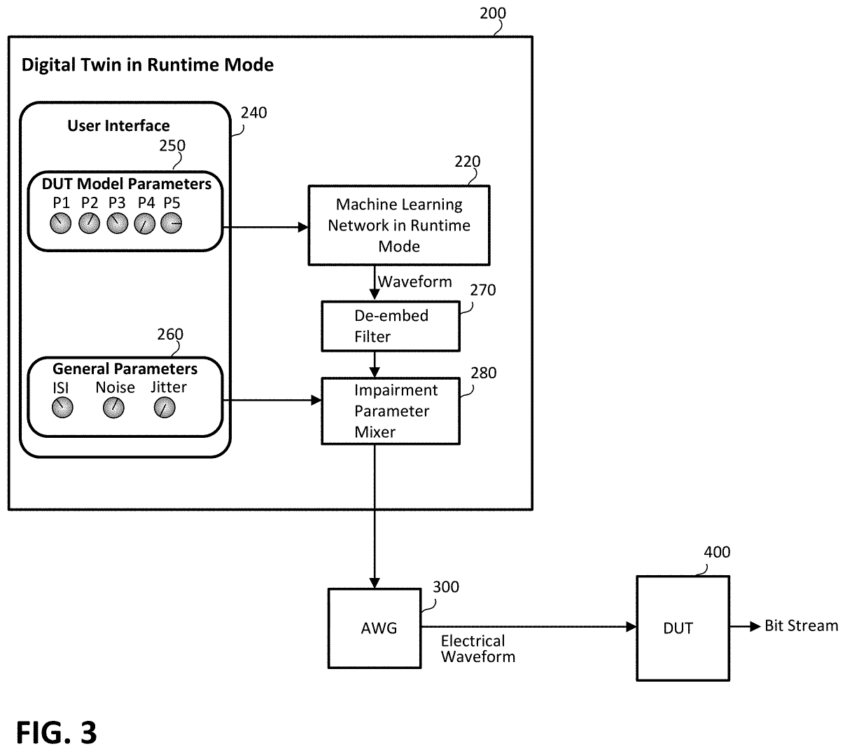

FIG. 3 is a system block diagram of a trained machine learning network in the digital twin device 200 used to generate simulated waveforms based on user inputs, according to embodiments of the disclosure. In this operation mode, the digital twin device 200 generates a waveform, or waveform signal, that causes an Arbitrary Waveform Generator 300 to generate an analog electrical waveform. The generated analog electrical waveform may be sent to a DUT 400 for testing. The DUT 400 may be a receiver, for example, which is used to test the interoperability with the various waveforms that are stored in the digital twin device 200.

The user interface 240 includes a DUT model parameter panel 250 through which the user can select particular values for the parameters to generate the desired waveform. The DUT model parameter panel 250 may be a graphical user interface, or may be controlled through programmatic commands. The particular parameters illustrated in the DUT model parameter panel 250 match those parameters that were used to train the machine learning network 220 in systems 50 and 60 above. Recall from above that the machine learning network 220 was trained to associate a particular waveform with a particular set of parameters. In this run-time mode, the user selects parameters using the DUT model parameter panel 250. Then, the machine learning network 220 generates the best waveform, or signal indicative of the waveform, as its output from the machine learning network 220 based on the exact parameter settings in the DUT model parameter panel 250. Recall that, during training, the machine learning network 220 closely associated particular waveforms as metadata to parameters used to generate the waveform. Now, in this run-time mode, the machine learning network works in reverse—generating the waveform based on the parameters that were used to originally create it. In operation, as the user adjusts the individual parameters in the DUT model parameter panel 250, the machine learning network 220 generates a waveform that most closely matches the selected parameters. In other embodiments, the output from the machine learning network 220 may be used as an index to a previously-classified waveform storage database. In this embodiment, the output from the machine learning network 220 may be used to select one of the waveforms previously presented to the machine learning network as being closest related to one of the set of parameter values previously swept.

After the waveform is selected and output by the machine learning network 220, a de-embedding filter 270 may be optionally applied to compensate the waveform for characteristics that the waveform experiences through the signal path in the AWG 300, such as in a Digital to Analog Converter (DAC) within the AWG 300.

Embodiments may further include a general impairment parameter panel 260, which may be used to further modify the waveform generated by the machine learning network 220. By selecting elements of the general impairment parameter panel 260, the user is able to modify the waveform generated by the machine learning network 220 to more accurately reflect a waveform as it would appear from the actual device, rather than as an unmodified output from the machine learning network 220. For instance, the user may add factors like noise, jitter, Intersymbol Interference (ISI), or other factors, to the waveform in an impairment parameter mixer 280 before being sent to the AWG 300. The filtering generated by the general impairment parameters 260 creates controllable impairments to the waveform to mimic how the waveform would be modified through a physical transmission link. In some embodiments, the impairment parameter mixer 280 may precede the de-embed filter 270.

Using the digital twin 200 and AWG 300 in the manner described above provides the user with parameter control like what they would control in a waveform-generating device once it is actually built and working, but the digital twin 200 may be available long before the device is built. This modeling through use of the digital twin 200 allows a less expensive design cycle by testing the concepts of the design prior to physically building the device.

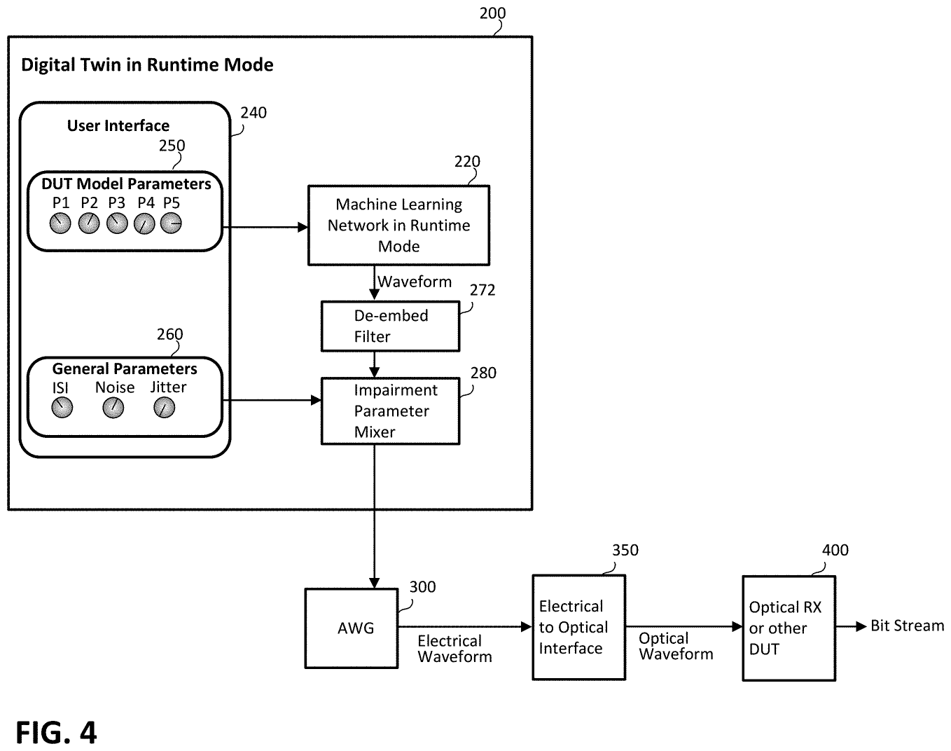

FIG. 4 is a system block diagram of a trained machine learning network in the digital twin device 200 used to generate simulated waveforms based on user inputs. Additionally, in FIG. 4, after the electrical waveform is generated by the AWG 300, it is applied to an electrical-to-optical interface 350, which converts the electrical waveform output of the AWG 300 to an optical waveform. Then the optical waveform may be applied to an optical receiver 400, or other device structured to receive optical signals. In the digital twin 200, a de-embed filter 272 may be optimized for the differences in optical-to-electrical changes during the training session as well as for the electrical-to-optical changes during run-time. Otherwise, the de-embed filter 272 operates the same or similar to the de-embedding filter 270 as described above with reference to FIG. 3.

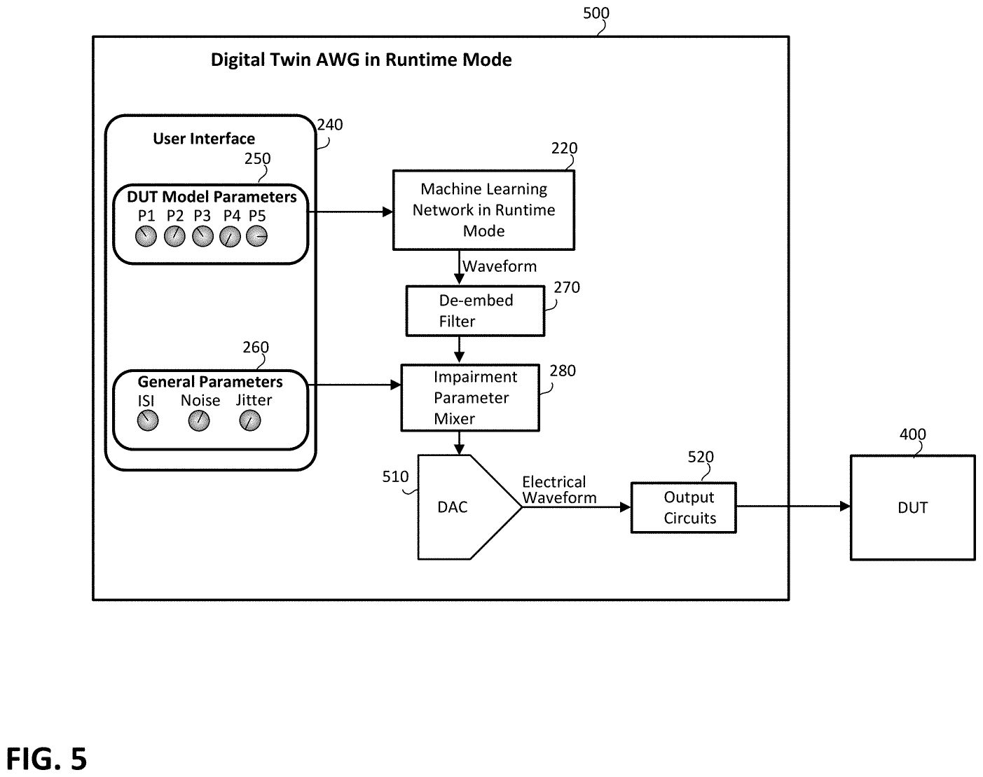

FIG. 5 is a system block diagram of an arbitrary waveform generator 500 including the machine learning network 220 for generating electrical waveforms, according to embodiments of the disclosure. The arbitrary waveform generator 500 of FIG. 5 is similar to the digital twin 200 of FIG. 3, except that the arbitrary waveform generator 500 includes circuitry to generate an output waveform in itself, without needing to be coupled to an external AWG, such as the AWG 300 of FIG. 3. Specifically, a Digital to Analog Converter (DAC) 510 accepts a digital waveform selected by the machine learning network 220, and as modified by the de-embed filter 270 and impairment parameter mixer 280. Then, the DAC 510 converts the digital waveform to an analog waveform signal. The analog waveform signal may be modified by one or more output circuits 520 to condition the output waveform for final output of the arbitrary waveform generator 500. The output circuits 520 may include one or more amplifiers, buffers, or other conditioning circuits, for example.

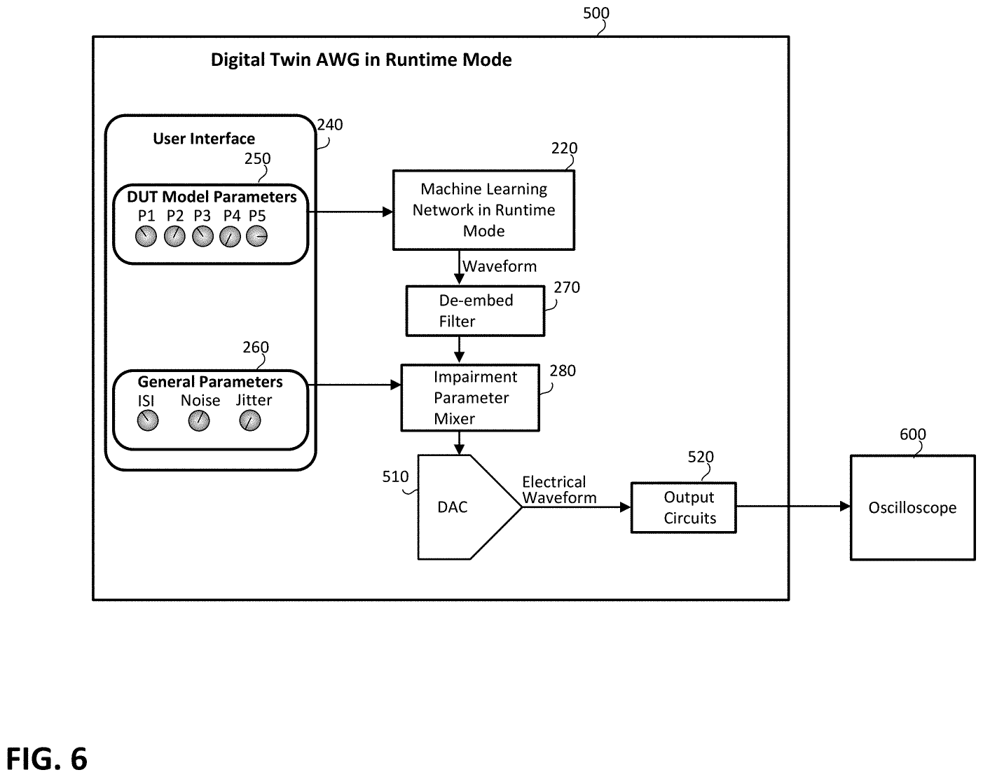

The final analog waveform output from the arbitrary waveform generator 500 may be sent to a DUT 400 for analysis, or, as described below, may be used for other purposes. The system illustrated in FIG. 5 may be used for testing Peripheral Component Interconnect Express, or other data transmission paths. For example, the arbitrary waveform generator 500 can be helpful to an R&D engineer who wants to better understand the interactions between the parameters of the device when those parameters are adjusted. Consider a case where the arbitrary waveform generator 500 generates relatively short data patterns that update live and interactively on an oscilloscope screen, such as an oscilloscope 600 of FIG. 6. By adjusting the DUT model parameters 250 of the arbitrary waveform generator 500, the user may be able to see, in real time, how particular parameters affect the outgoing waveform. It could be the case that modifying a particular parameter makes very little difference in the ultimate waveform output. Or, it could be the case that a small modification in a single parameter may make a large difference to the waveform generated by the machine learning network 220 and output by the waveform generator 500. In either case, coupling the arbitrary waveform generator 500 to the oscilloscope 600 allows the user to view the effect of parameter adjustments in real-time. Further, using the oscilloscope 600 to view the waveforms generated by the machine learning network 220 allows the user to inspect the quality of the training of the machine learning network during the training stage, which was described above.

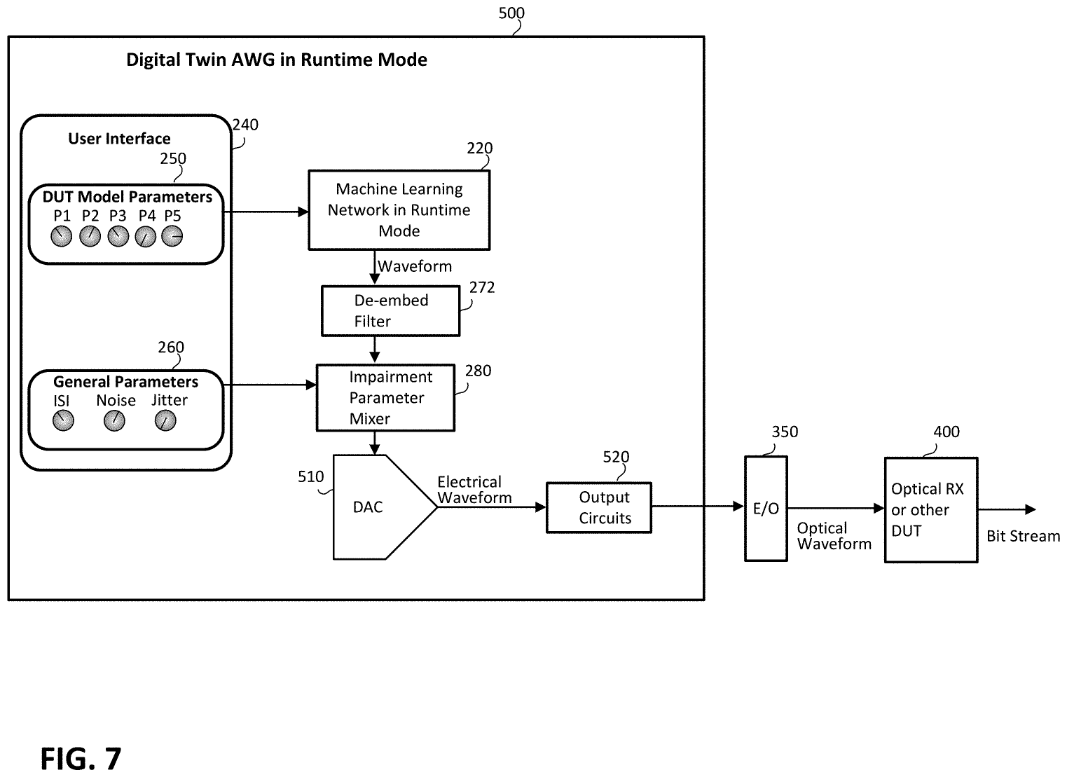

FIG. 7 is a system block diagram of an arbitrary waveform generator 500 including a machine learning network 220 for generating optical waveforms based on user inputs, according to embodiments of the disclosure. The arbitrary waveform generator 500 of FIG. 7 is similar to the digital twin device 200 of FIG. 4, in that it is coupled to the electrical-to-optical interface 350, which converts the electrical waveform output from the arbitrary waveform generator 500 to an optical waveform. Then, the optical waveform may be presented to an optical receiver 400, or other DUT for testing. A main difference between the arbitrary waveform generator 500 of FIG. 7 and the digital twin device 200 of FIG. 4 is the presence of the DAC 510, as described in detail above.

Aspects of the disclosure, including the digital twin device 200 and/or the arbitrary waveform generator 500 may operate on a particularly created hardware, on firmware, digital signal processors, or on a specially programmed general purpose computer including a processor operating according to programmed instructions. The terms controller or processor as used herein are intended to include microprocessors, microcomputers, Application Specific Integrated Circuits (ASICs), and dedicated hardware controllers. One or more aspects of the disclosure may be embodied in computer-usable data and computer-executable instructions, such as in one or more program modules, executed by one or more computers (including monitoring modules), or other devices. Generally, program modules include routines, programs, objects, components, data structures, etc. that perform particular tasks or implement particular abstract data types when executed by a processor in a computer or other device. The computer executable instructions may be stored on a non-transitory computer readable medium such as a hard disk, optical disk, removable storage media, solid state memory, Random Access Memory (RAM), etc. As will be appreciated by one of skill in the art, the functionality of the program modules may be combined or distributed as desired in various aspects. In addition, the functionality may be embodied in whole or in part in firmware or hardware equivalents such as integrated circuits, FPGA, and the like. Particular data structures may be used to more effectively implement one or more aspects of the disclosure, and such data structures are contemplated within the scope of computer executable instructions and computer-usable data described herein.

The disclosed aspects may be implemented, in some cases, in hardware, firmware, software, or any combination thereof. The disclosed aspects may also be implemented as instructions carried by or stored on one or more or non-transitory computer-readable media, which may be read and executed by one or more processors. Such instructions may be referred to as a computer program product. Computer-readable media, as discussed herein, means any media that can be accessed by a computing device. By way of example, and not limitation, computer-readable media may comprise computer storage media and communication media.

Computer storage media means any medium that can be used to store computer-readable information. By way of example, and not limitation, computer storage media may include RAM, ROM, Electrically Erasable Programmable Read-Only Memory (EEPROM), flash memory or other memory technology, Compact Disc Read Only Memory (CD-ROM), Digital Video Disc (DVD), or other optical disk storage, magnetic cassettes, magnetic tape, magnetic disk storage or other magnetic storage devices, and any other volatile or nonvolatile, removable or non-removable media implemented in any technology. Computer storage media excludes signals per se and transitory forms of signal transmission.

Communication media means any media that can be used for the communication of computer-readable information. By way of example, and not limitation, communication media may include coaxial cables, fiber-optic cables, air, or any other media suitable for the communication of electrical, optical, Radio Frequency (RF), infrared, acoustic or other types of signals.

### EXAMPLES

Illustrative examples of the disclosed technologies are provided below. An embodiment of the technologies may include one or more, and any combination of, the examples described below.

Example 1 is a device for generating waveforms, including a machine learning system configured to associate waveforms as metadata to parameters that describe conditions that generated the waveforms, a user interface configured to allow a user to provide one or more user inputs and one or more processors configured to execute code that causes the one or more processors to receive one or more inputs through the user interface, the one or more user inputs at least including one or more parameters apply the machine learning system to the received one or more parameters produce, by the machine learning system, a waveform based on the one or more parameters, and output the produced waveform.

Example 2 is a device for generating waveforms according to Example 1, further comprising, in a training mode, a test automation system to send sets of parameters to the device under test, acquire resulting waveforms from the device under test, and send the sets of parameters and the resulting waveforms to the machine learning system as training input.

Example 3 is a device for generating waveforms according to Example 2, in which the test automation system includes a parameter generator and a test and measurement instrument to acquire waveforms from the device under test.

Example 4 is a device for generating waveforms according to Example 3, in which the parameter generator is configured to sweep through multiple values of one or more parameters to generate the sets of parameters.

Example 5 is a device for generating waveforms according to any of the preceding Examples, in which the produced waveform is output in digital form, the device further comprising a digital-to-analog converter to convert the digital form of the produced waveform to an analog form of the produced waveform.

Example 6 is a device for generating waveforms according to Example 5, in which the analog form of the produced waveform is presented to an electrical-to-optical interface.

Example 7 is a device for generating waveforms according to Example 6, in which the device further comprises a de-embed filter for applying electrical-to-optical compensation to the produced waveform prior to conversion by the digital-to-analog converter.

Example 8 is a device for generating waveforms according to any of the preceding Examples, in which the device further comprises an impairment parameter mixer for applying one or more impairments to the produced waveform.

Example 9 is a device for generating waveforms according to Example 8, in which the user interface is structured to receive an impairment selection from a user.

Example 10 is a device for generating waveforms according to any of the preceding Examples, in which the one or more processors are further structured to execute code that causes the one or more processors to train the machine learning system by creating associations in the machine learning system between the waveforms and parameters.

Example 11 is a method for generating waveforms by a device including a machine learning system, the method including accepting one or more parameters through a user interface, applying the machine learning system to the accepted one or more parameters, producing, by the machine learning system, a waveform based on the one or more parameters, and outputting the produced waveform.

Example 12 is a method according to Example 11, further comprising training the machine learning system with output from a waveform simulation device.

Example 13 is a method according to any of the preceding Example methods, further comprising training the machine learning system with output from a test automation system, in which the test automation system includes a parameter generator to send sets of parameters to a device under test and a test and measurement instrument to acquire waveforms from the device under test operating according to the sets of parameters.

Example 14 is a method according to any of the preceding Example methods, in which the produced waveform is output in digital form, further comprising converting the produced waveform to an analog form.

Example 15 is a method according to Example 14, further comprising presenting the analog form of the produced waveform to an electrical-to-optical interface.

Example 16 is a method according to Example 15, further comprising applying electrical-to-optical compensation to the produced waveform prior to converting the produced waveform to the analog form.

Example 17 is a method according to any of the preceding Example methods, further comprising applying one or more impairments to the produced waveform.

Example 18 is a method according to Example 17, further comprising receiving one or more selected impairments from a user.

Example 19 is a method according to any of the preceding Example methods, further comprising training the machine learning system by creating associations in the machine learning system between the accepted parameters and associated waveform metadata.

Additionally, this written description makes reference to particular features. It is to be understood that the disclosure in this specification includes all possible combinations of those particular features. For example, where a particular feature is disclosed in the context of a particular aspect, that feature can also be used, to the extent possible, in the context of other aspects.

Also, when reference is made in this application to a method having two or more defined steps or operations, the defined steps or operations can be carried out in any order or simultaneously, unless the context excludes those possibilities.

Although specific aspects of the disclosure have been illustrated and described for purposes of illustration, it will be understood that various modifications may be made without departing from the spirit and scope of the disclosure. Accordingly, the disclosure should not be limited except as by the appended claims.

We claim:

1. A device for generating waveforms, comprising:
a machine learning system configured to associate waveforms as metadata to parameters that describe conditions that generated the waveforms;
a user interface configured to allow a user to provide one or more user inputs; and
one or more processors configured to execute code that causes the one or more processors to:
receive one or more inputs through the user interface, the one or more user inputs at least including one or more parameters,
apply the machine learning system to the received one or more parameters,
produce, by the machine learning system, a waveform based on the one or more parameters; and
output the produced waveform.

2. The device for generating waveforms according to claim 1, further comprising, in a training mode, a test automation system to send sets of parameters to the device under test, acquire resulting waveforms from the device under test, and send the sets of parameters and the resulting waveforms to the machine learning system as training input.

3. The device for generating waveforms according to claim 2, in which the test automation system includes a parameter generator and a test and measurement instrument to acquire waveforms from the device under test.

4. The device for generating waveforms according to claim 3, in which the parameter generator is configured to sweep through multiple values of one or more parameters to generate the sets of parameters.

5. The device for generating waveforms according to claim 1, in which the produced waveform is output in digital form, the device further comprising a digital-to-analog converter to convert the digital form of the produced waveform to an analog form of the produced waveform.

6. The device for generating waveforms according to claim 5, in which the analog form of the produced waveform is presented to an electrical-to-optical interface.

7. The device for generating waveforms according to claim 6, in which the device further comprises a de-embed filter for applying electrical-to-optical compensation to the produced waveform prior to conversion by the digital-to-analog converter.

8. The device for generating waveforms according to claim 1, in which the device further comprises an impairment parameter mixer for applying one or more impairments to the produced waveform.

9. The device for generating waveforms according to claim 8, in which the user interface is structured to receive an impairment selection from a user.

10. The device for generating waveforms according to claim 1, in which the one or more processors are further structured to execute code that causes the one or more processors to train the machine learning system by creating associations in the machine learning system between the waveforms and parameters.

11. A method for generating waveforms by a device including a machine learning system, the method comprising:
accepting one or more parameters through a user interface;
applying the machine learning system to the accepted one or more parameters, producing, by the machine learning system, a waveform based on the one or more parameters; and
outputting the produced waveform.

12. The method for generating waveforms according to claim 11, further comprising training the machine learning system with output from a waveform simulation device.

13. The method for generating waveforms according to claim 11 further comprising training the machine learning system with output from a test automation system, in which the test automation system includes a parameter generator to send sets of parameters to a device under test and a test and measurement instrument to acquire waveforms from the device under test operating according to the sets of parameters.

14. The method for generating waveforms according to claim 11, in which the produced waveform is output in digital form, further comprising converting the produced waveform to an analog form.

15. The method for generating waveforms according to claim 14, further comprising presenting the analog form of the produced waveform to an electrical-to-optical interface.

16. The method for generating waveforms according to claim 15, further comprising applying electrical-to-optical compensation to the produced waveform prior to converting the produced waveform to the analog form.

17. The method for generating waveforms according to claim 11, further comprising applying one or more impairments to the produced waveform.

18. The method for generating waveforms according to claim 17, further comprising receiving one or more selected impairments from a user.

19. The method for generating waveforms according to claim 11, further comprising training the machine learning system by creating associations in the machine learning system between the accepted parameters and associated waveform metadata.
